(19) United States
(12) Patent Application Publication
(10) Pub. No.: US 2010/0201361 A1
(43) Pub. Date: Aug. 12, 2010

(54) SYSTEM AND METHOD FOR PASSIVE CATHETER TRACKING WITH MAGNETIC RESONANCE IMAGING

(76) Inventor: Robert R. Edelman, Highland Park, IL (US)

Correspondence Address: QUARLES & BRADY LLP, 411 E. WISCONSIN AVENUE, SUITE 2040, MILWAUKEE, WI, 53202-4497, US

(21) Appl. No.: 12/726,974

(22) Filed: Mar. 18, 2010

Related U.S. Application Data
(63) Continuation-in-part of application No. 12/114,990, filed on May 5, 2008, now abandoned.
(60) Provisional application No. 60/915,781, filed on May 3, 2007.

(51) Int. Cl. G01R 33/48

(52) U.S. Cl. 324/309

(57) ABSTRACT

Background tissue signals such as water and/or fat are suppressed in an MR image by using an imaging agent that chemically shifts the tissue spins of interest. An imaging pulse sequence is used to acquire the image data using an RF excitation pulse that is tuned to the off-resonance tissue spins of interest with the saturation pulse sequences being interleaved with the imaging pulse sequences to selectively suppress signals from on-resonance background tissues such as water and/or fat.

### CROSS-REFERENCE TO RELATED APPLICATIONS

This application is a continuation-in-part of, and incorporates herein by reference, U.S. patent application Ser. No. 12/114,990, filed on May 5, 2008, and entitled “Magnetic Resonance Image Acquisition with Suppression of Background Tissues and RF Water Excitation at Offset Frequency,” which is based on, and claims the benefit of, U.S. Provisional Patent Application Ser. No. 60/915,781, filed on May 3, 2007, and entitled “Magnetic Resonance Image Acquisition with Suppression of Background Tissues and RF Water Excitation at Offset Frequency.”

### BACKGROUND OF THE INVENTION

The field of the invention is magnetic resonance imaging (“MRI”) methods and systems and particularly the use of tissue suppression in conjunction with the use of a radio frequency (“RF”) excitation pulse for water at an offset or off-resonance frequency. That is an RF excitation pulse for water at a frequency that is shifted from a nominal Larmor frequency of water.

Any nucleus that possesses a magnetic moment attempts to align itself with the direction of a magnetic field in which it is located. In doing so, however, the nucleus precesses around this direction at a characteristic frequency that is termed the Larmor frequency, ω₀, and that is dependent on the strength of the magnetic field and on the gyromagnetic constant, γ, of the nucleus. That is, ω₀=γB, where γ=42.56 MHz/T for hydrogen nuclei, and B is the strength of the magnetic field. Hydrogen is the spin species of choice for most MRI applications and, for example, the Larmor frequency, ω₀, for hydrogen nuclei in a 1.5 Tesla (“T”) magnetic field is 63.8 megahertz (“MHz”).

MRI takes advantage of this phenomenon by subjecting an object to be imaged, such as human tissue, to a uniform magnetic field (polarizing field B₀). When a substance such as human tissue is subjected to this magnetic field, B₀, the individual magnetic moments of the nuclei in the tissue attempt to align with this polarizing field, but precess about it in random order at their characteristic Larmor frequency. If the substance, or tissue, is subjected to a magnetic field (excitation field B₁) that is in the x-y plane and that is near the Larmor frequency, the net aligned moment, M_{z}, may be rotated, or “tipped,” into the x-y plane to produce a net transverse magnetic moment M_{xy}. A signal is emitted by the excited nuclei or “spins,” after the excitation signal B₁ is terminated, and this signal may be received and processed to form an image.

In MRI systems, the excited spins induce an oscillating sine wave signal in a receiving coil. The frequency of this signal is near the Larmor frequency, and its initial amplitude, A₀, is determined by the magnitude of the transverse magnetic moment, M_{xy}. The amplitude, A, of the emitted nuclear magnetic resonance (“NMR”) signal decays in an exponential fashion with time, t. The decay constant, 1/T₂*, depends on the homogeneity of the magnetic field and on T₂, which is referred to as the “spin-spin relaxation” constant, or the “transverse relaxation” constant. The T₂ constant is inversely proportional to the exponential rate at which the aligned precession of the spins would dephase after removal of the excitation signal, B₁, in a perfectly homogeneous field. The practical value of the T₂ constant is that tissues have different T₂ values and this can be exploited as a means of enhancing the contrast between such tissues.

Another important factor that contributes to the amplitude, A, of the NMR signal is referred to as the spin-lattice relaxation process that is characterized by the time constant, T₁. The spin-lattice relaxation process describes the recovery of the net magnetic moment, M, to its equilibrium value along the axis of magnetic polarization, such as the z-axis. The T₁ time constant is longer than T₂, and indeed is much longer in most substances of medical interest. As with the T₂ constant, the difference in T₁ between tissues can be exploited to provide image contrast.

When utilizing these “MR” signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received MR signals are digitized and processed to reconstruct the image using one of many well known reconstruction techniques.

The measurement cycle used to acquire each MR signal is performed under the direction of a pulse sequence produced by a pulse sequencer. Clinically available MRI systems store a library of such pulse sequences that can be prescribed to meet the needs of many different clinical applications. Research MRI systems include a library of clinically-proven pulse sequences and they also enable the development of new pulse sequences.

The MR signals acquired with an MRI system are signal samples of the subject of the examination in Fourier space, or what is often referred to in the art as “k-space.” Each MR measurement cycle, or pulse sequence, typically samples a portion of k-space along a sampling trajectory characteristic of that pulse sequence. Most pulse sequences sample k-space in a raster scan-like pattern sometimes referred to as a “spin-warp,” a “Fourier,” a “rectilinear,” or a “Cartesian” scan. The spin-warp scan technique employs a variable amplitude phase encoding magnetic field gradient pulse prior to the acquisition of MR spin-echo signals to phase encode spatial information in the direction of this gradient. In a two-dimensional implementation (“2DFT”), for example, spatial information is encoded in one direction by applying a phase encoding gradient, G_{y}, along that direction, and then a spin-echo signal is acquired in the presence of a readout magnetic field gradient, Gₓ, in a direction orthogonal to the phase encoding direction. The readout gradient present during the spin-echo acquisition encodes spatial information in the orthogonal direction. In a typical 2DFT pulse sequence, the magnitude of the phase encoding gradient pulse, G_{y}, is incremented, ΔG_{y}, in the sequence of measurement cycles, or “views” that are acquired during the scan to produce a set of k-space MR data from which an entire image can be reconstructed.

The ability to depict anatomy and pathology by MRI is critically dependent on the contrast, or difference in signal intensities between the target and background tissues. In order to maximize contrast, it is necessary to suppress the signal intensities of the background tissues. For instance, small blood vessels are much better depicted by the techniques of magnetic resonance angiography (“MRA”) when the signal intensities of fat, muscle, and other background tissues are minimized.

To enhance the diagnostic capability of MRA a contrast agent such as gadolinium can be injected into the patient prior to the MRA scan. As described in U.S. Pat. No. 5,417,213, contrast enhanced MRA (“CEMRA”) attempts to acquire the central k-space views at the moment the bolus of contrast agent is flowing through the vasculature of interest. Collection of the central lines of k-space during peak arterial enhancement is key to the success of a CEMRA exam. If the central lines of k-space are acquired prior to the arrival of contrast, severe image artifacts can limit the diagnostic information in the image. Alternatively, arterial images acquired after the passage of the peak arterial contrast are sometimes obscured by the enhancement of veins. In many anatomic regions, such as the carotid or renal arteries, the separation between arterial and venous enhancement can be as short as six seconds.

The ability to time the arrival of contrast in the vasculature of interest varies considerably and it is helpful in many applications to acquire a series of MRA images in a dynamic study which depicts the separate enhancement of arteries and veins. Such a temporal series of images is also useful for observing delayed vessel filling patterns caused by disease. This requirement has been partially addressed by acquiring a series of time resolved images using a 3D “Fourier” acquisition as described by F. Korosec, et al., in “Time-Resolved Contrast-Enhanced 3D MR Angiography,” Magn. Reson. Med., 1996; 36:345-351, and in U.S. Pat. No. 5,713,358. More recently, time-resolved MRA images have been acquired using a three-dimensional projection reconstruction method as described in U.S. Pat. No. 6,487,435, entitled “Magnetic Resonance Angiography Using Undersampled 3D Projection Imaging.”

With CEMRA image studies the usual practice is to acquire at least one image prior to the injection of contrast into the patient. This pre-contrast image is used as a mask that is subtracted from the contrast enhanced images to remove the signal from surrounding non-vascular tissues and fat. While this technique can be very effective, it does have two disadvantages. First, it extends the time of the scan and it requires that the patient be immobilized so that the mask image is precisely registered with the contrast enhanced images from which it is subtracted. Any misregistration results in distracting image artifacts that may interfere with the diagnostic utility of the angiogram. The subtraction of two images also increases the standard deviation of the noise signal, reducing the signal-to-noise ratio (“SNR”) by the square root of two.

A unique property of MRI is the ability to selectively image different chemical species by virtue of what is known as the chemical shift phenomenon. The specific frequency that a hydrogen proton absorbs is dependent not only on the applied magnetic field, B₀, but also on its surroundings. For example, in the human body, the bulk of the hydrogen MR signals arise from two sources: water and fat, with fat exhibiting a Larmor frequency that is separated from the water frequency by approximately 3.5 parts per million (“ppm”). At a field strength of 2 T this equates to a frequency separation of about 280 Hz in the NMR spectrum. Silicone also exhibits a chemical shift of approximately 5 ppm. This chemical shift has been exploited by a number of different techniques used to suppress signals from undesired tissues or to enhance signals from target tissues.

Various techniques for suppression of fat, generally referred to as “FATSAT,” are well known in the art. Fat suppression is usually achieved by placing a narrow band spectral suppression pulse before the imaging sequence. This pre-pulse is quickly followed by the imaging sequence so that the fat protons do not have time to relax back to their equilibrium magnetization which remains dispersed (saturated) and unable to contribute signal to the image.

Reference is now made to FIG. 2, which is an illustration of a prior-art 3D gradient-echo motion compensated pulse sequence having a frequency selective simple Gaussian FATSAT spectral suppression pulse, which is centered on or tuned to the fat frequency. The double-headed arrow labeled Tₚ represents the pre-saturation sequence, and the double-headed arrow labeled TR represents the imaging sequence. The graph labeled RF represents the RF imaging sequence, which includes a Gaussian spectral suppression pre-pulse 2 followed by an imaging RF pulse 3 having a flip angle, α.

The graphs labeled “Slice Select,” “Phase Encode,” and “Readout” represent the slice selection gradient, the phase encoding gradient, and the viewing, or readout, gradient sequences, respectively. The slice selection gradient sequence includes a three-lobed motion compensated gradient 5, a phase encoding gradient 6 and a rewinder gradient 7. The gradient pulse referenced 4 is a spoiler pulse that is part of the pre-saturation sequence Tₚ. The phase encoding axis sequence includes a phase encoding gradient 8 and a rewinder gradient 9. The viewing gradient sequence includes a readout gradient 10. The graph labeled “Signal” is the NMR signal 11.

Reference is now made to FIG. 3, which is a graph representing a prior-art NMR spectrum of fat and water protons on which a fat Gaussian spectral suppression pulse is superimposed. The horizontal axis represents the chemical shift in parts per million (“ppm”) units. The curve labeled 14 represents the absorption spectrum of fat and water protons. The dashed line labeled W indicates the peak absorption of the water protons at zero ppm and the dashed line labeled F indicates the peak of absorption of the fat protons, which is shifted by 3.5 ppm relative to the peak absorption of the water protons. The excitation spectrum of a typical fat Gaussian spectral suppression pulse 16 is superimposed on the absorption spectrum curve 14. The Gaussian suppression pulse 16 is centered at the peak F and will thus selectively excite the fat protons without substantial excitation of the water protons. Suppression pulses using the since cardinal (“sinc”) function are also known in the art.

Gaussian and sinc-type suppression pulses are required to be long in duration in order to achieve a suitably narrow spectral selection. At a field strength of 2 Tesla a typical sinc suppression pulse may take up to 26 ms.

Reference is now made to FIG. 4, which is an illustration of a prior-art 3D gradient-echo imaging sequence having a frequency selective binomial FATSAT spectral suppression pre-saturation pulse 1 that is centered on the water frequency. The fat suppression sequence of FIG. 4 uses a 1-3-3-1 binomial suppression pulse 1 which is centered around the water frequency. The use of binomial pulse suppression techniques is disclosed in an article appearing in The Journal of Magnetic Resonance, entitled “Solvent Suppression in Fourier Transform Nuclear Magnetic Resonance” by P. J. Hore (Vol. 55, 1983, pp. 283-300) incorporated herein by reference.

The gradient-echo sequence of FIG. 4 is similar to the gradient-echo sequence of FIG. 2, except that the RF imaging sequence which includes a gaussian spectral suppression pre-pulse 2 of FIG. 4 includes a 1-3-3-1 binomial suppression pulse 1 instead of the Gaussian spectral suppression pre-pulse 2. The 1-3-3-1 binomial suppression pulse 1 includes four sub-pulses 1A, 1B, 1C and 1D, which are separated from each other by a pulse separation interval, τ.

By choosing the appropriate pulse separation interval, τ, (dependent upon field strength and chemical species) the binomial pulse 1 exhibits a null excitation at the water frequency which rises to a 90 degree excitation at the fat frequency.

Reference is now made to FIG. 5, which is a schematic graph illustrating the theoretical excitation spectrum of a prior art 1-3-3-1 binomial suppression pulse as a function of frequency offset from the transmitter frequency. The vertical axis of the graph represents the transverse magnetization M_{xy} wherein full scale corresponds to complete conversion of the z-axis longitudinal magnetization into the x-y plane transverse magnetization. The transverse magnetization curve 40 has a flat excitation null 42 around the transmitter frequency.

The binomial pulse sequence shown in FIG. 4 has a total duration of approximately 5.4 ms at 2 Tesla. This is somewhat shorter than the Gaussian pulse 2 of FIG. 2, but requires a high RF power because of the short “hard” pulses.

Suppression techniques generally extend the minimum TR that can be used and result in a reduction in the number of slices that can be imaged in a multi-slice sequence. They are also limited when short TR's are required since rapid, repeated, and incomplete, saturation of the fat frequency inevitably leads to a build up of coherent fat signal resulting in image artifacts.

Methods of spectral-spatial excitation use a carefully designed RF modulation in the presence of an oscillating gradient to excite the target tissues. The result is a simultaneous selection along one spatial axis and the frequency spectrum. The use of Spectral-spatial excitation is disclosed in an article appearing in Magnetic Resonance in Medicine, entitled “Simultaneous Spatial and Spectral selective Excitation” by Craig H. Meyer et al. (Vol. 15, 1990, pp. 287-304), incorporated herein by reference.

FIG. 6 is a graph illustrating imaging sequences designed for a prior art spectral-spatial excitation method. The graph labeled RF represents the RF “fat free” imaging sequence. The gradient sequence labeled G_{z} is a modulated slice selection gradient. The gradient sequences labeled Gₓ and G_{y} are spiral readout gradients. Each of the gradients Gₓ, G_{y}, and G_{z} is shown as having a rephasing pulse at the far end of the gradient pulse trains.

The frequency of the modulated gradient is calculated so that, when centered on the water resonance, an excitation null occurs at the fat resonance. In this way only the water resonance is excited. This kind of pulse is usually incorporated directly into the imaging sequence since it is designed to select the desired slice profile only at the water frequency.

Reference is now made to FIG. 7, which is a graph illustrating a prior art rapid gradient-echo pulse sequence using a spectral-spatial pulse with Gaussian k-space varying along both k_{z} and k_{ω} as disclosed by Meyer et al. The graphs labeled RFI and RFQ represent the real and the imaginary components of the RF “fat free” imaging sequence, respectively. The gradient sequence labeled “Slice Select” is a modulated slice selection gradient. The gradient sequence labeled “Readout” is a readout gradient. The gradient sequence “Phase Encode” is a phase encoding gradient. This pulse sequence results in compact spatial and spectral slice profiles (not shown) which are Gaussian in shape in the small-tip-angle regime.

Spectral-spatial techniques have the advantage of exciting only the chemical species of interest. Because of this, no sacrifice is necessary on the repetition time (TR). However, spectral-spatial pulses are limited by gradient performance and are especially limited for low field applications where they are prohibitively long in duration. Additionally, careful optimization is required to ensure good spectral selection.

Certain compounds are known to shift the Larmor frequency of spins located in the immediate vicinity of the compound. As disclosed in published U.S. Patent Appln. No. 2006/0058642, three compounds in the lanthanide family are notable for their chemical shifting abilities. These are dysprosium (Dy), praseodymium (Pr), and europium (Eu), and, when administered to a subject under MRI examination, the Larmor frequency of water spins may be shifted away from the Larmor frequency of fat, making the suppression of fat signals much easier to achieve.

Standard angiographic catheters typically have a small lumen, which is challenging to visualize and track during MR-guided endovascular procedures. Bulk magnetic susceptibility (“BMS”) effects for long, cylindrical geometries, such as those common to catheters, are sensitive to orientation with respect to the static magnetic field, B₀. As a result, methods that employ off-resonance contrast enhancement in the presence of a contrast agent passing through the catheter, which can be utilized to shift the Larmor frequency of water spins adjacent the catheter, are unreliable for passive tracking of the catheter.

### SUMMARY OF THE INVENTION

The present invention is based on the discovery that imaging agents of various forms can shift the Larmor frequency of adjacent water spins. The present invention recognizes that these shifted water spins can be imaged by using an RF excitation pulse that is centered on the shifted Larmor frequency to perform off-resonance contrast imaging processes.

For example, one such imaging method uses parametric contrast agents, such as those based on gadolinium, which not only shorten the T₁ relaxation of adjacent water spins, but they also produce a chemical shift of the Larmor frequency of those water spins. Other imaging agents can also be used to shift the Larmor frequency of adjacent water spins, such as catheters including a frequency shifting agent. For example, a catheter having a coating or filled with material such as gadolinium, can be used. This provides the potential for passive catheter tracking. However, one drawback is the sensitivity of the gadolinium induced frequency shifts to the orientation of the catheter.

One aspect of the invention is the provision of shaped catheter coatings that shift the resonance frequency and can substantially eliminate the orientation dependence of the frequency shift. For example, the use of a loop in the catheter can overcome these bulk magnetic susceptibility (“BMS”) orientation effects.

Another approach may include the application of a spherical-shaped, super-paramagnetic coating to a guidewire placed within a catheter. The immediate surroundings of such a spherical coating can be visualized in both parallel and perpendicular orientations at the same frequency shift. Different regions adjoining the spherical coating are seen depending on whether a positive or negative frequency offset is used for excitation.

In accordance with one aspect of the present invention, a contrast agent is administered to a subject and an image is acquired using an imaging pulse sequence in which the RF excitation pulse is tuned to the chemically shifted water spins. The imaging acquisition is interleaved with saturation pulse sequences having an RF saturation pulse tuned to fat and water spins that are not chemically shifted by the contrast agent.

A general focus of the invention is to acquire contrast enhanced MRA images without the need to subtract a mask image. The saturation pulse sequences are performed throughout the acquisition at a rate which keeps the signals from tissues surrounding the subject's vasculature suppressed without significantly affecting the signal from blood that contains the contrast agent. In addition, the contrast agent performs its usual function of shortening the T₁ relaxation time of the blood such that many imaging pulse sequences can be performed before the saturated and non-T₁ shortened surrounding tissues recover enough to require another saturation pulse sequence. Thus, the scan is not significantly increased in time.

The foregoing and other aspects and advantages of the invention will appear from the following description. In the description, reference is made to the accompanying drawings which form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1 is a block diagram of an MRI system which employs the present invention;

FIGS. 2-7 are graphic representations of prior-art methods for selectively suppressing or enhancing tissue signals;

FIG. 8 is a graphic representation of an imaging pulse sequence in accordance with the present invention;

FIG. 9 is a graphic representation of a saturation pulse sequence used with the imaging pulse sequence of FIG. 8;

FIG. 10 is a flow chart of the steps performed by the MRI system of FIG. 1 when practicing the present invention.

FIG. 11 is an exemplary catheter system that is adaptable for passive tracking by the MRI system of FIG. 1;

FIG. 12 is an exemplary configuration of a looped portion of the catheter shaft the forms a part of the catheter system of FIG. 11;

FIG. 13A is an exemplary configuration of a plurality of markers affixed to a portion of the catheter shaft that forms a part of the catheter system of FIG. 11;

FIG. 13B is an exemplary configuration of a marker affixed to a portion of the catheter shaft that forms a part of the catheter system of FIG. 11;

FIG. 14 is a cross-sectional view of the marker of FIG. 13 along view line 14-14;

FIG. 15 is a cross-sectional view of an alternative configuration of the marker illustrated in FIG. 13B; and

FIGS. 16A-16C are exemplary configurations of a guidewire in accordance with the present invention that forms a part of the catheter system of FIG. 11.

### DETAILED DESCRIPTION OF THE INVENTION

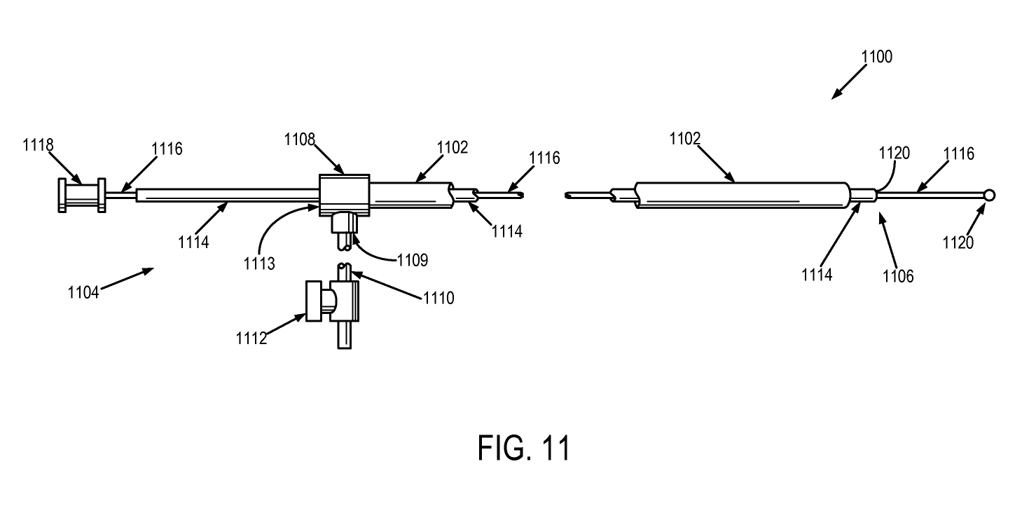

Referring to FIG. 11, a catheter system 1100 that is amenable to passive tracking with a magnetic resonance imaging (“MRI”) system includes a flexible shaft 1102 having a length suitable for reaching a vasculature of interest from a selected vessel entry point. Exemplary lengths include 80, 110, and 135 centimeters (“cm”). The flexible shaft 1102 extends from a proximal end (shown generally by arrow 1104) towards a distal end (shown generally by arrow 1106), and is composed, for example, of a plastic. In some configurations, the catheter shaft 1102 has a diameter of five French (“5F”); however, it will be appreciated by those skilled in the art that different diameters can be readily employed depending on the desired angiographic procedure. At its proximal end 1104, the shaft 1102 connects to a fixture 1108 that defines an inlet 1109 to the interior of the shaft 1102 and connects that inlet 1109 through a tube 1110 to a valve 1112. The fixture 1108 also provides an opening 1113 that enables a guidewire shaft 1114 to exit from the proximal end 1104 of the shaft 1102.

A guidewire 1116 extends through a guidewire shaft lumen 1117 (FIGS. 14 and 15) formed in the guidewire shaft 1114 and terminates at its proximal end with a grip 1118, which enables the guidewire 1116 to be manipulated. In turn, the guidewire shaft extends through a lumen 1103 (FIGS. 14 and 15) formed in the catheter shaft 1102. In accordance with the present invention, the guidewire 1116 can include a tip 1120 that is affixed to the distal end 1106 of the guidewire 1116. The tip 1120 serves two functions. First, the tip 1120 allows the guidewire 1116 to be manipulated and extended through vessels by maneuvering the grip 1118. Second, the tip 1120, through its composition and configuration described in detail below, produces an off-resonance contrast enhancement in images obtained by directing an MRI system to perform a pulse sequence, such as the one described below and in co-pending U.S. patent application Ser. No. 11/834,754, which is herein incorporated by reference in its entirety.

A fluid, such as a gadolinium chelate contrast agent, can be injected into the catheter 1100 through the valve 1112 as shown in FIG. 11. The fluid passes through the interior of the catheter shaft 1102 and flows into the vessel via an opening 1122 at the distal end of the guidewire shaft 1114.

It should be apparent to those skilled in the art that the catheter 1100 enables the passive tracking of the catheter during many different MR-guided angiographic procedures that are to be performed at or near a vessel of interest.

It should also be apparent to those skilled in the art that the catheter shaft 1102 may contain as many inner shafts as are necessary for the desired angiographic procedure. In the configuration described above, a single guidewire shaft 1114 is provided and defines a guidewire shaft lumen 1117 for a guidewire 1116. If the angiographic procedure at task requires the use of an inflatable balloon, a separate inflation lumen (not shown) can be formed in the catheter shaft 1102 for the delivery and inflation of an inflatable balloon to the vascular region of interest. For example, the lumen 1103 of the catheter shaft 1102 may be divided into two separate lumens by a wall, which divides the cylindrical volume of the catheter shaft 1102 into two separate parts.

It should be apparent to those skilled in the art that the catheter can further be configured to provide a stent (not shown) to the vascular region of interest. In this configuration, it is contemplated that the use of the contrast media tipped guidewire or a marked catheter shaft is more applicable than a looped catheter shaft configurations, as the latter configuration may interfere with the stent delivery.

To provide passive tracking of the catheter 1100, an MRI system is directed to perform a pulse sequence that elicits an off-resonance contrast enhancement of a portion of the catheter 1100. An exemplary pulse sequence of this kind is described below in detail; however, in general, the pulse sequence relies on the principle that materials having a significant bulk magnetic susceptibility (“BMS”) affect the magnetic resonance, or Larmor, frequency of those nuclear spins adjacent the material. By tuning a radio frequency (“RF”) excitation field to the shifted resonance frequency of water spins adjacent a material having such a significant BMS, and by saturating the water spins whose resonance frequency is not shifted, images depicting substantially only the material having the significant BMS are obtained. A difficulty arises, however, in that this off-resonance contrast mechanism relies on a proper alignment of the BMS with the main magnetic field, B₀, of the MRI system. For example, when the BMS is aligned at an angle of around 55 degrees with the main magnetic field, B₀, substantially no shifting of adjacent resonance frequencies occurs. However, when BMS is substantially perpendicular to the main magnetic field, B₀, then the resonance frequency shift effect is substantially maximized. Moreover, if the BMS is parallel with the main magnetic field, B₀, then the resonance frequency shift effect is around one-half of the substantially maximal amount.

Thus, a portion of the catheter 1100 is configured such that it ensures that a material having a significant BMS is kept substantially perpendicular to the main magnetic field, B₀, of the MRI system regardless of the orientation of the catheter 1100.

One exemplary configuration of a catheter 1100 in accordance with the present invention is illustrated in FIG. 12. The catheter 1100 includes a loop 1202 formed in the catheter shaft 1102. The loop 1202 is formed such that is allows for the passage of the guidewire 1116, and is sized such that is allows for the maneuvering of the catheter 1100 through the vasculature. In such a configuration, the catheter 1100 includes a lumen through which a contrast agent can be provided. Exemplary contrast agents include a gadolinium chelate. When the contrast agent is directed through the loop 1202 at a sufficient rate and concentration to elicit the described off-resonance contrast enhancement effect, the water spins adjacent the loop 1202 will experience a shift in their resonance frequency. As a result, the loop 1202 is readily depicted in images obtained with the off-resonance contrast enhancement. Because at least a portion of the loop 1202 extends in a plane away from the center line of the catheter shaft 1102, a portion of the contrast agent will be aligned at an appropriate angle with respect to the main magnetic field of the MRI system so that the desired contrast enhancement is produced. While this configuration has its advantages, namely its simple manufacture and its reliability, it is less applicable for smaller vessel geometries given the added spatial extent of the catheter 1100 provided by the loop 1202.

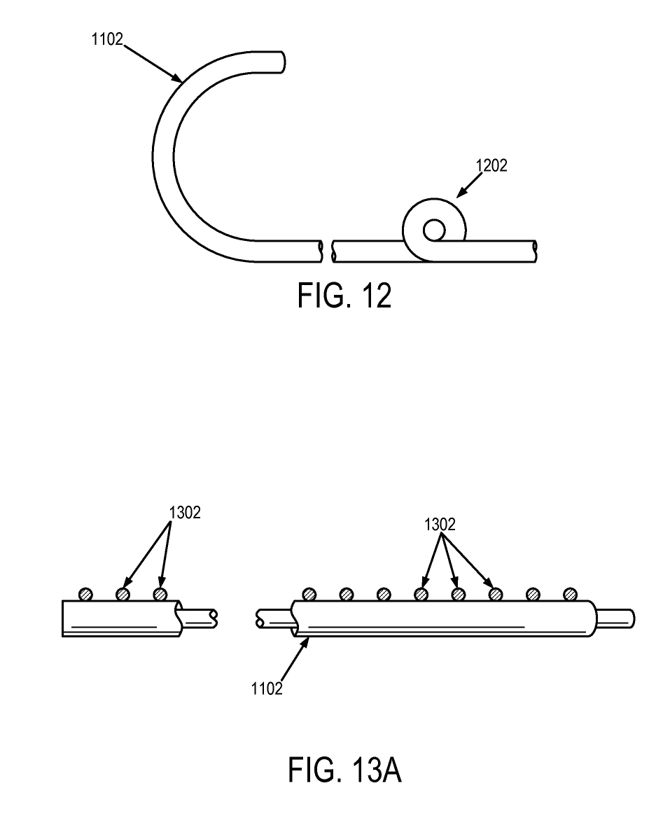

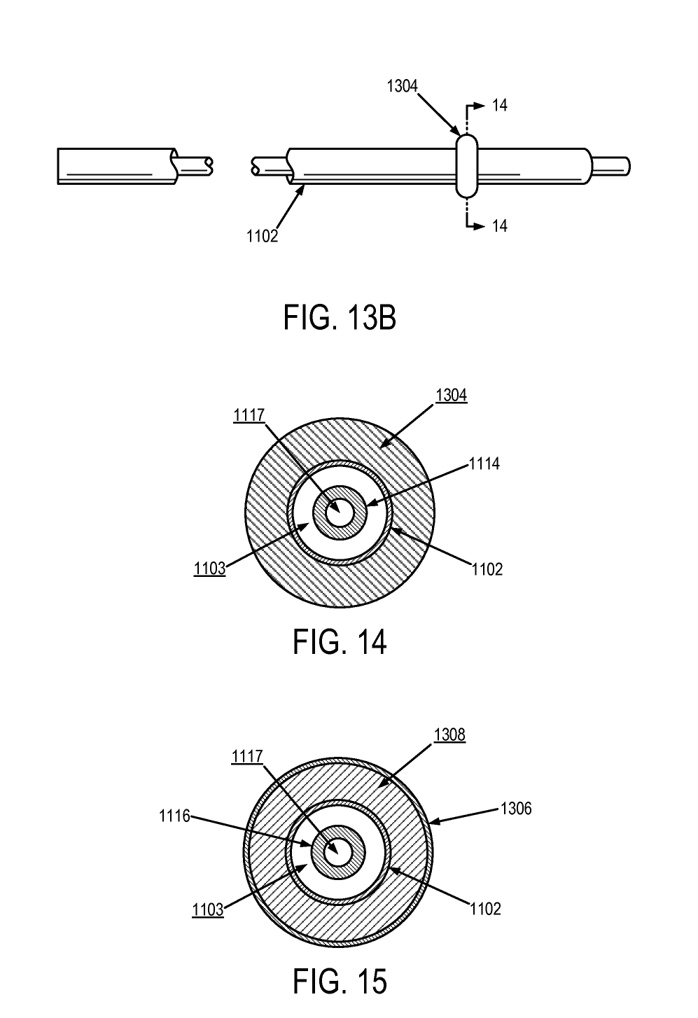

Another exemplary configuration of a catheter system 1100 in accordance with the present invention is illustrated in FIG. 13A. The catheter includes a plurality of markers 1302 that are formed on the outer surface of the catheter shaft 1102 and run along its length. The exemplary markers 1302 illustrated in FIG. 13A are substantially spherical in shape, but as will be mentioned below, other geometries are contemplated. The marker 1302 can either be a hollow encapsulation filled with a contrast material, such as gadolinium, or can be formed of a contrast material, such as an epoxy-iron oxide mixture, affixed to the outer surface of the catheter shaft 1102. When placed in the main magnetic field, B₀, of the MRI system, the epoxy-iron oxide mixture becomes magnetized and produces a bulk magnetic susceptibility that induces magnetic resonance frequency shifts in regions adjacent the mixture. The shape of the markers 1302 are selected such that a predetermined frequency shift is induced.

Another exemplary configuration of a catheter system 1100 in accordance with the present invention is illustrated in FIG. 13B. The catheter includes a marker 1304 that is formed about the catheter shaft 1102. The exemplary marker 1304 illustrated in FIG. 13 is toroidally shaped and, as shown in FIG. 14, is circumjacent to the outer surface of the catheter shaft 1102. The marker 1304 can either be formed of a contrast material, such as an epoxy-iron oxide mixture, affixed to the outer surface of the catheter shaft 1102, or, as shown in FIG. 15, can be a hollow encapsulation 1306 formed around the catheter shaft 1102 and filled with a contrast material 1308, such as gadolinium. Like the epoxy-iron oxide mixture described above, the gadolinium produces a bulk magnetic susceptibility that induces magnetic resonance frequency shifts in regions adjacent the mixture. The shape of the markers 1302 are selected such that a predetermined frequency shift is induced.

It should be appreciated by those skilled in the art that the marker 1304 need not be toroidally shaped. Alternatively, as noted above, the marker 1304 can be shaped as one or more spherical markers affixed to the outer surface of the catheter shaft 1102, as one or more spherical caps affixed to the outer surface of the catheter shaft 1102, and so on.

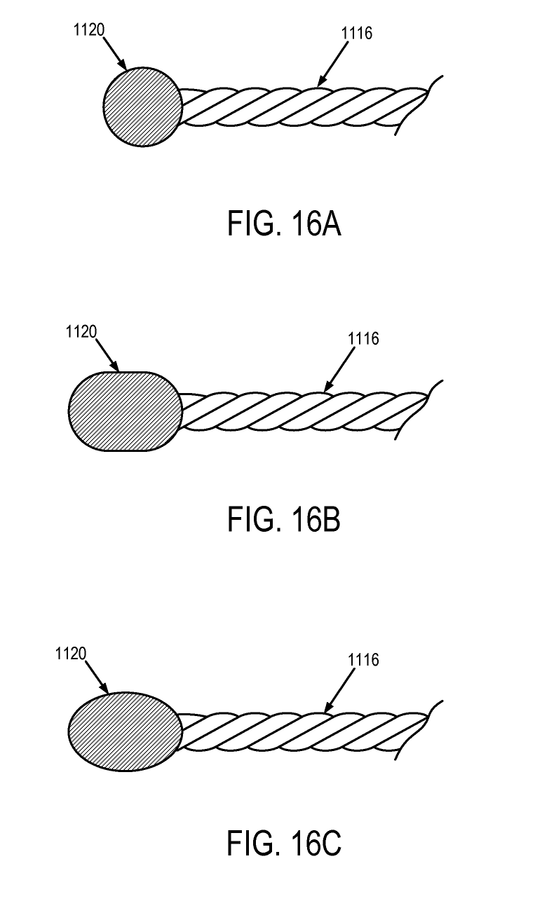

Another exemplary configuration of a catheter in accordance with the present invention includes a guidewire configured to elicit the desired off-resonance contrast enhancement in accordance with the present invention. Exemplary configurations of such a guidewire are illustrated in FIGS. 16A-16C. The guidewire 1116 is composed of a flexible material, such as nylon, and includes a tip 1120 that is composed of a material having a bulk magnetic susceptibility sufficient to elicit a frequency shift in the magnetic resonance frequencies of nuclear spins adjacent the tip, such as an epoxy-iron oxide mixture, and is shaped so that a substantially uniform shift is experienced by nuclear spins aligned along at least two directions extending outward from an extension axis of the guidewire 1116. The extension axis runs along the center of the guidewire 1116 from its proximal end to its distal end and is aligned along the direction of such extension. In some configurations, the tip 1120 of the guidewire 1116 is shaped to have a substantially circular cross-section, such that the aforementioned uniformity is achieved. In some configurations, the guidewire has a diameter of 35 mil (0.035 inches); however, different diameters can readily be employed with the selection of guidewire diameter being made based on the diameter of the guidewire shaft 1114 and the desired angiographic procedure. In general, the diameter of the guidewire is selected such that it is suitable to be maneuvered in the catheter system 1100.

An exemplary configuration of the guidewire tip 1120 is shaped as a sphere, as shown in FIG. 16A, such that a substantially uniform frequency shift is induced in regions adjacent the tip 1120 along substantially any direction extending outward from the center of the spherical tip.

Another exemplary configuration of the guidewire tip 1120 is shaped as a spheroid, as shown in FIG. 16B, such that a substantially uniform frequency shift is induced in regions adjacent the tip 1120 along at least two directions extending outward from the extension axis of the guidewire 1116.

Another exemplary configuration of the guidewire tip 1120 is shaped as an end-rounded cylinder, as shown in FIG. 16C, such that a substantially uniform frequency shift is induced in regions adjacent the tip 1120 along at least two directions extending outward from the extension axis of the guidewire 1116.

Other configurations of the guidewire tip 1120 are possible and will be apparent to those skilled in the art. For example, similar to the markers disposed along the length of the catheter shaft, similar spherical or other shaped markers could be disposed along a length of the guidewire. Further such exemplary configurations include ellipsoidal, cylindrical, elliptical cylindrical, and so on.

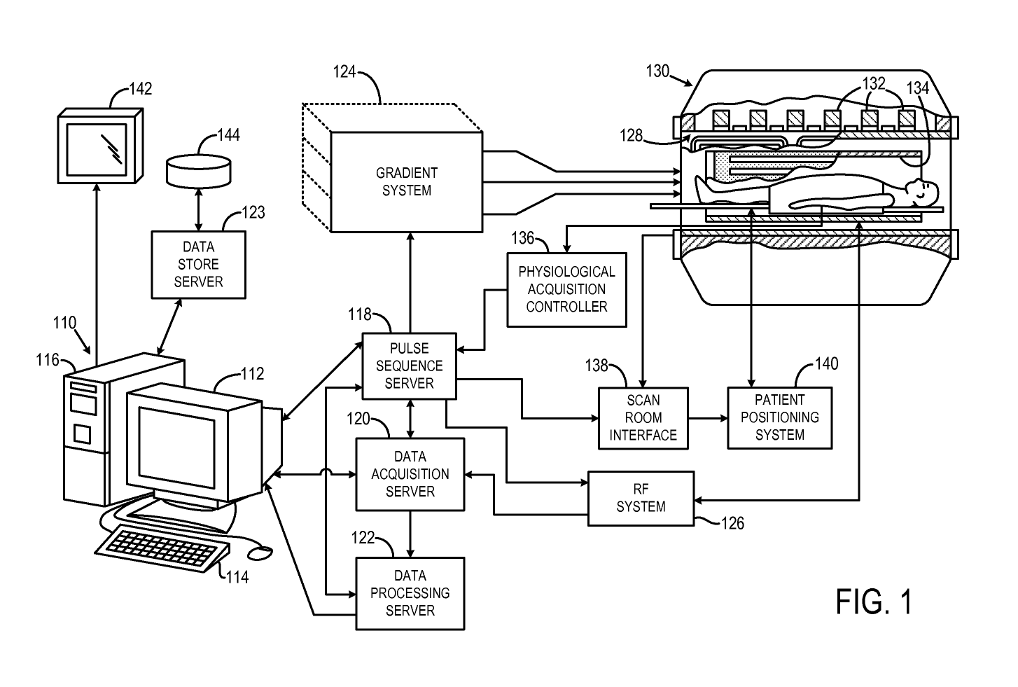

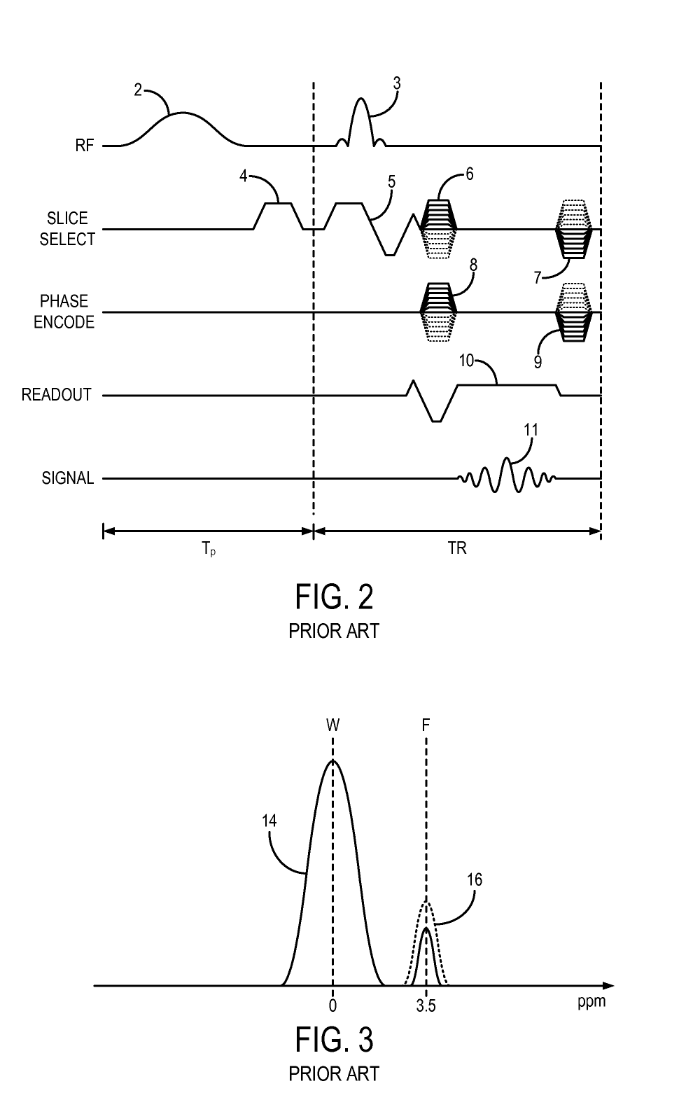

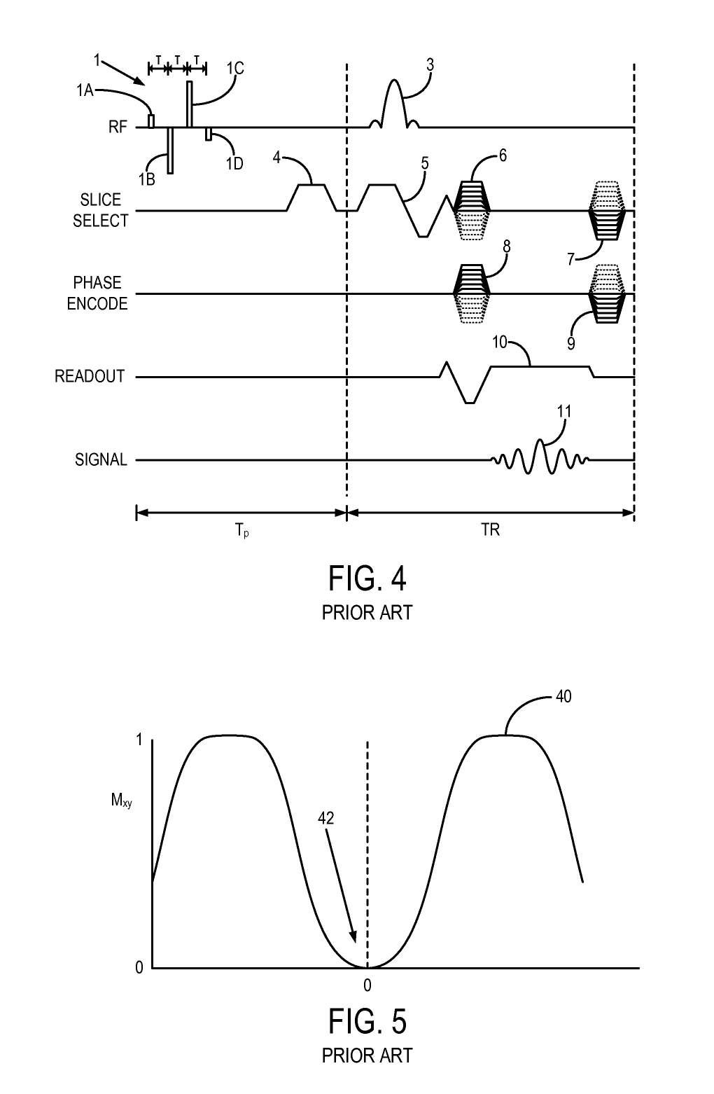

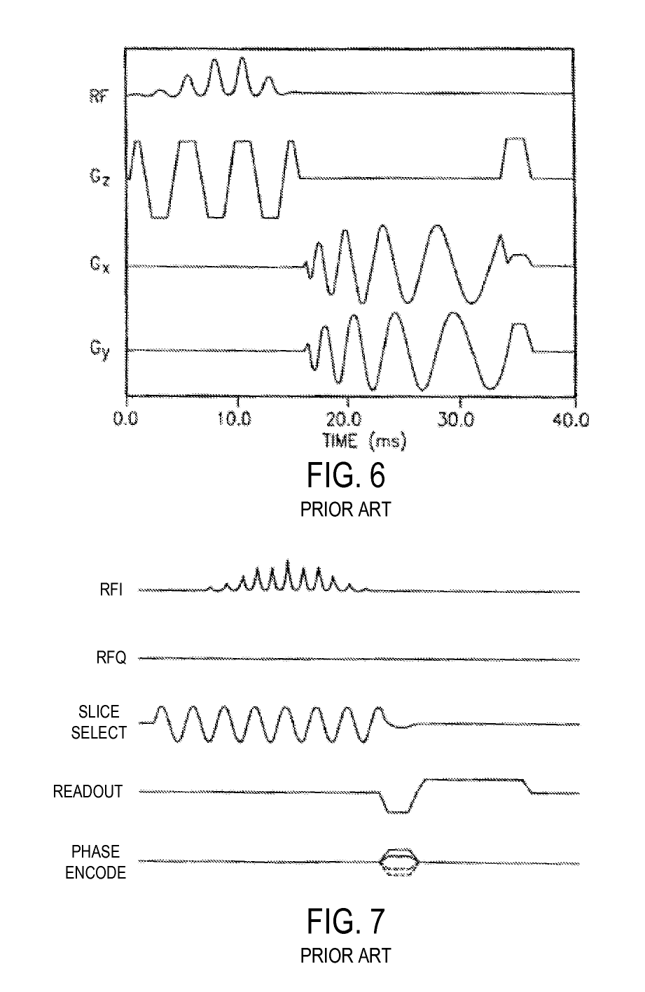

Referring particularly to FIG. 1, the preferred embodiment of the invention is employed in a magnetic resonance imaging (“MRI”) system. The MRI system includes a workstation 110 having a display 112 and a keyboard 114. The workstation 110 includes a processor 116 that is a commercially available programmable machine running a commercially available operating system. The workstation 110 provides the operator interface that enables scan prescriptions to be entered into the MRI system. The workstation 110 is coupled to four servers: a pulse sequence server 118; a data acquisition server 120; a data processing server 122, and a data store server 123. The workstation 110 and each server 118, 120, 122 and 123 are connected to communicate with each other.

The pulse sequence server 118 functions in response to instructions downloaded from the workstation 110 to operate a gradient system 124 and a radiofrequency (“RF”) system 126. Gradient waveforms necessary to perform the prescribed scan are produced and applied to the gradient system 124 that excites gradient coils in an assembly 128 to produce the magnetic field gradients Gₓ, G_{y}, and G_{z} used for position encoding MR signals. The gradient coil assembly 128 forms part of a magnet assembly 130 that includes a polarizing magnet 132 and a whole-body RF coil 134.

RF excitation waveforms are applied to the RF coil 134 by the RF system 126 to perform the prescribed magnetic resonance pulse sequence. Responsive MR signals detected by the RF coil 134 or a separate local coil (not shown in FIG. 1) are received by the RF system 126, amplified, demodulated, filtered and digitized under direction of commands produced by the pulse sequence server 118. The RF system 126 includes an RF transmitter for producing a wide variety of RF pulses used in MR pulse sequences. The RF transmitter is responsive to the scan prescription and direction from the pulse sequence server 118 to produce RF pulses of the desired frequency, phase and pulse amplitude waveform. The generated RF pulses may be applied to the whole body RF coil 134 or to one or more local coils or coil arrays (not shown in FIG. 1).

The RF system 126 also includes one or more RF receiver channels. Each RF receiver channel includes an RF amplifier that amplifies the MR signal received by the coil to which it is connected and a detector that detects and digitizes the I and Q quadrature components of the received MR signal. The magnitude of the received MR signal may thus be determined at any sampled point by the square root of the sum of the squares of the I and Q components:

M=\sqrt{I²+Q²} Eqn. (1);

and the phase of the received MR signal may also be determined:

$$φ = {tan}^{- 1} ( \frac{Q}{I} ) . \qquad Eqn . ( 2 )$$

The pulse sequence server 118 also optionally receives patient data from a physiological acquisition controller 136. The controller 136 receives signals from a number of different sensors connected to the patient, such as ECG signals from electrodes or respiratory signals from a bellows. Such signals are typically used by the pulse sequence server 118 to synchronize, or “gate,” the performance of the scan with the subject's respiration or heart beat.

The pulse sequence server 118 also connects to a scan room interface circuit 138 that receives signals from various sensors associated with the condition of the patient and the magnet system. It is also through the scan room interface circuit 138 that a patient positioning system 140 receives commands to move the patient to desired positions during the scan.

The digitized MR signal samples produced by the RF system 126 are received by the data acquisition server 120. The data acquisition server 120 operates in response to instructions downloaded from the workstation 110 to receive the real-time MR data and provide buffer storage such that no data is lost by data overrun. In some scans the data acquisition server 120 does little more than pass the acquired MR data to the data processor server 122. However, in scans that require information derived from acquired MR data to control the further performance of the scan, the data acquisition server 120 is programmed to produce such information and convey it to the pulse sequence server 118. For example, during prescans MR data is acquired and used to calibrate the pulse sequence performed by the pulse sequence server 118. Also, navigator signals may be acquired during a scan and used to adjust RF or gradient system operating parameters or to control the view order in which k-space is sampled. And, the data acquisition server 120 may be employed to process MR signals used to detect the arrival of contrast agent in a magnetic resonance angiography (MRA) scan. In all these examples the data acquisition server 120 acquires MR data and processes it in real-time to produce information that is used to control the scan.

The data processing server 122 receives MR data from the data acquisition server 120 and processes it in accordance with instructions downloaded from the workstation 110. Such processing may include, for example: Fourier transformation of raw k-space MR data to produce two or three-dimensional images; the application of filters to a reconstructed image; the performance of a backprojection image reconstruction of acquired MR data; the calculation of functional MR images; and the calculation of motion or flow images.

Images reconstructed by the data processing server 122 are conveyed back to the workstation 110 where they are stored. Real-time images are stored in a data base memory cache (not shown) from which they may be output to operator display 112 or a display 142 that is located near the magnet assembly 130 for use by attending physicians. Batch mode images or selected real time images are stored in a host database on disc storage 144. When such images have been reconstructed and transferred to storage, the data processing server 122 notifies the data store server 123 on the workstation 110. The workstation 110 may be used by an operator to archive the images, produce films, or send the images via a network to other facilities.

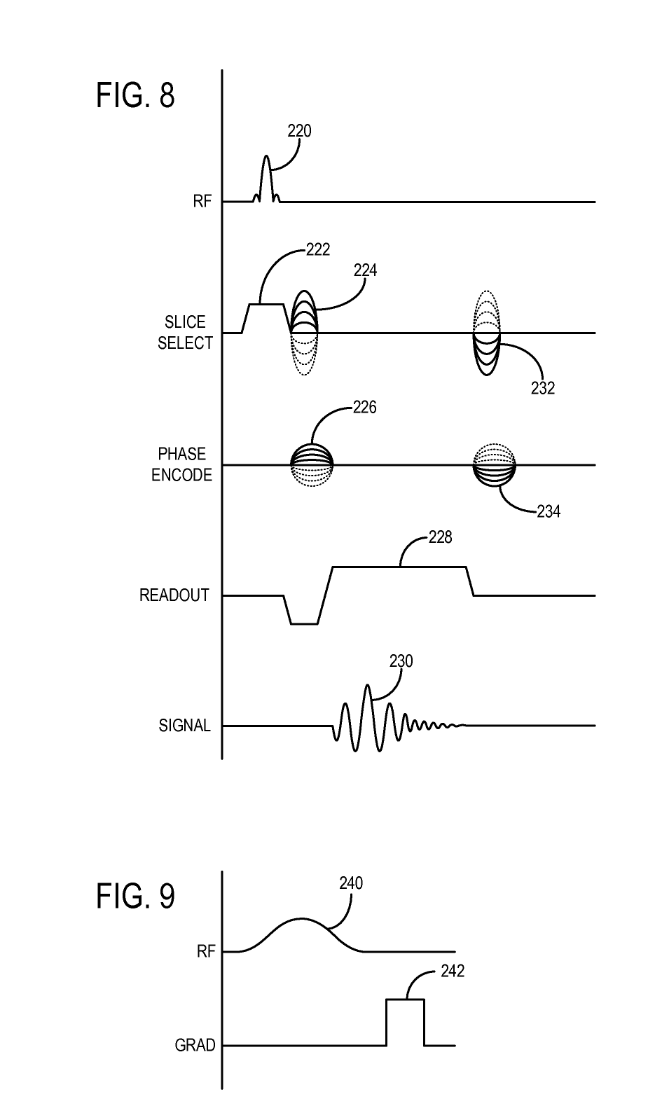

While the present invention may be used with many different imaging pulse sequences, in one embodiment a three-dimensional, spoiled gradient-echo pulse sequence is used with a sampling bandwidth of 83-125 kHz. Referring to FIG. 8, an RF excitation pulse 220 having a flip angle of 15-60 degrees is produced in the presence of a slab select gradient pulse 222 to produce transverse magnetization in the 3D volume of interest. In the alternative, a spectrally-selective, spatially non-selective RF excitation pulse may be used, in which case, no slab select gradient pulse is required. In either case, the RF excitation pulse is followed by a phase encoding gradient pulse 224 directed along the z-axis and a phase encoding gradient pulse 226 directed along the y axis. A readout gradient pulse 228 directed along the x axis follows and a partial echo (for example, 60%) NMR signal 230 is acquired and digitized as described above. After the acquisition, rewinder gradient pulses 232 and 234 rephase the magnetization before the pulse sequence is repeated. As is well known in the art, the pulse sequence is repeated and the phase encoding pulses 224 and 226 are stepped through a series of values to sample the 3D k-space.

Sampling along the kₓ axis is performed by sampling the echo signal 230 in the presence of the readout gradient pulse 228 during each pulse sequence. It will be understood by those skilled in the art that only a partial sampling along the kₓ axis is performed and the missing data is computed using a homodyne reconstruction or by zero filling. This enables the echo time (TE) of the pulse sequence to be shortened to 1-2 ms and the pulse repetition rate (TR) to be shortened to 3-6 ms.

The RF excitation pulse 220 in this imaging pulse sequence is tuned to excite water spins that have been chemically shifted by an administered paramagnetic contrast agent. The amount of this chemical shift depends on the type and concentration of the contrast agent, but in the one embodiment gadolinium-DTPA is used and typical frequency shifts are given in Table 1.

TABLE 1

| B₀ | Chemical Shift |
|---|---|
| 1.5 T | 225 Hz |
| 3.0 T | 450 Hz |
| 7.0 T | 1050 Hz |

The excitation pulse 220 may also be spectrally selective to the off-resonance water spins. A number of different approaches can be used to provide spectral selectively, but because the TE and TR times of the imaging pulse sequence should be kept very short, the effectiveness of spectral selectivity is limited.

The suppression of signals from background tissues is achieved primarily by interleaving a saturation pulse sequence with the image pulse sequence repetitions. Referring to FIG. 9, the saturation pulse sequence includes a spectrally selective RF saturation pulse 240, followed by a spoiler gradient pulse 242. The saturation pulse 240 in this embodiment is a frequency selective Gaussian saturation pulse with the flip angle of 110 degrees that is tuned to a frequency midway between the Larmor frequency of fat and the Larmor frequency of on-resonance water. Since the saturation pulse sequence is performed far less often than the imaging pulse sequence, the duration of the RF saturation pulse 240 is not as important and it may be extended to insure adequate selection of on-resonance, background tissues without substantially affecting the off-resonance water spins. The spoiler gradient 242 dephases the transverse magnetization produced by the saturation pulse 240.

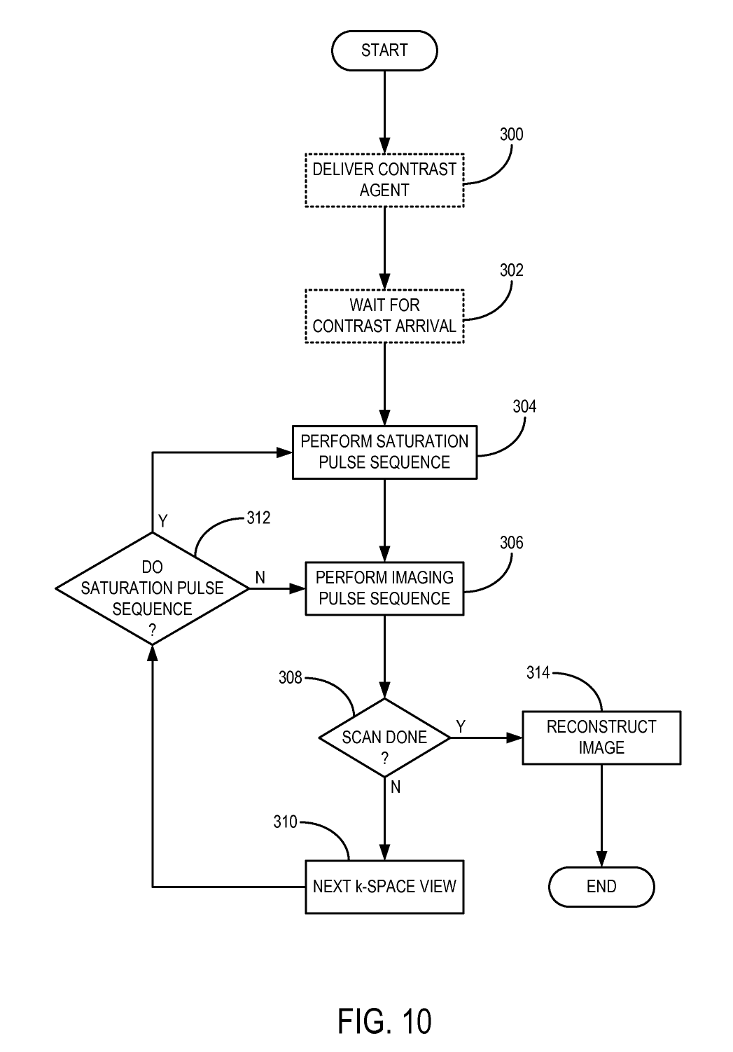

Referring to FIG. 10, a scan is conducted to acquire one or more images using the imaging pulse sequence of FIG. 8. As indicated at process block 300, a contrast agent is optionally first directed through the catheter. This step is optionally performed when using a configuration of the catheter that includes a loop, such as the configuration described above with respect to FIG. 12. An exemplary contrast agent has a significant bulk magnetic susceptibility, such as a gadolinium chelate. When using the gadolinium chelate, at least 0.2 millimolar per kilogram of body weight (“mmol/kg”) of the contrast agent is directed through the catheter, and at a rate of at least 3 cubic centimeters per second (“cc/sec”). The system pauses until the contrast agent enters the catheter as indicated at process block 302 and a loop is then entered in which the image data is acquired.

As indicated at process block 304, the above-described saturation pulse sequence is performed to saturate the on-resonance spins in the region of interest. Then the above-described imaging pulse sequence is performed as indicated at process block 306 to acquire a single view of k-space data. A check is then made at decision block 308 to determine if all the k-space data for the prescribed image (or images) have been acquired. If not, the gradients for the next view are determined as indicated at process block 310 and the system loops back to acquire the next view.

Before acquiring the next view, however, a check is made at decision block 312 to determine if the saturation pulse sequence should be performed first. Typically, from 4-128 imaging pulse sequences can be performed before the longitudinal magnetization of surrounding on-resonance background tissues recovers from the previous saturation pulse sequence. The exact number of views acquired between saturation pulse sequences forms part of the scan prescription. Either the imaging pulse sequence is performed, or if the prescribed number of image views has been acquired, the saturation pulse sequence is performed first.

When all the image data has been acquired as determined at decision block 308, the acquired k-space data is used to reconstruct one or more images as indicated at process block 314. A conventional image reconstruction method is used such as a 3DFT.

It should be apparent that many different imaging pulse sequences can be employed without departing from the spirit of the invention. An important factor, however, is that the RF excitation pulses used in the imaging pulse sequence be tuned to the off-resonance frequency of the contrast enhanced spins. Also, various types of known spectrally selective RF pulses may be used in both the imaging pulse sequence and the saturation pulse sequence.

The present invention has been described in terms of one or more preferred embodiments, and it should be appreciated that many equivalents, alternatives, variations, and modifications, aside from those expressly stated, are possible and within the scope of the invention.

1. A catheter for passive tracking with a magnetic resonance imaging (MRI) system, the catheter comprising:
a shaft formed from a flexible material extending along an axis from a proximal end to a distal end and configured for insertion into a blood vessel;
a lumen extending through the shaft from the proximal end to the distal end; and
at least one marker affixed to the shaft and including a contrast media having a bulk magnetic susceptibility that shifts magnetic resonance frequencies of regions adjacent the at least one marker by a predetermined amount.

2. The catheter as recited in claim 1 in which the at least one marker includes a plurality of spherically shaped markers affixed to an outer surface of the shaft and spaced along a length of the shaft between the proximal end and the distal end of the axis of the shaft.

3. The catheter as recited in claim 1 in which the at least one marker is substantially toroidally shaped and extends substantially about the shaft substantially transverse to the shaft.

4. The catheter as recited in claim 1 in which the at least one marker is at least one of substantially shaped as a sphere and substantially shaped as a spherical cap formed on an outer surface of the shaft.

5. The catheter as recited in claim 1 further comprising a guidewire for passive tracking with an MRI system and configured to be positioned within the lumen, the guidewire comprising:
a flexible wire extending along an extension axis from a proximal end to a distal end; and
a tip affixed to the distal end, wherein the tip is composed of a material having a bulk magnetic susceptibility that shifts magnetic resonance frequencies of regions in at least two directions extending outward from the extension axis of the wire by a predetermined amount.

6. The catheter as recited in claim 5 in which the tip has a substantially circular cross section in a plane transverse to the extension axis of the wire.

7. A guidewire for passive tracking with a magnetic resonance imaging (MRI) system and configured to be positioned within a catheter, the guidewire comprising:
a flexible wire extending along an extension axis from a proximal end to a distal end; and
a tip affixed to the distal end, wherein the tip is composed of a material having a bulk magnetic susceptibility that shifts magnetic resonance frequencies of regions in at least two directions extending outward from the extension axis of the wire by a predetermined amount.

8. The guidewire as recited in claim 7 in which the at least two directions are orthogonal.

9. The guidewire as recited in claim 7 in which the tip has a substantially circular cross section in a plane transverse to the extension axis of the wire.

10. The guidewire as recited in claim 7 in which the tip is shaped in at least one of an ellipsoidal shape, a spheroidal shape, a spherical shape, a cylindrical shape, an ellipsoidal cylindrical shape, and an end-rounded cylindrical shape.

11. The guidewire as recited in claim 7 in which the wire is composed of nylon.

12. The guidewire as recited in claim 7 in which the tip is composed of at least iron oxide.

13. The guidewire as recited in claim 7 in which the tip is affixed to the distal end by an epoxy.

14. The guidewire as recited in claim 13 in which the tip comprises a mixture of the epoxy and iron oxide.

15. The guidewire as recited in claim 7 further comprising at least one marker affixed to the flexible wire and comprising a contrast media having a bulk magnetic susceptibility that shifts magnetic resonance frequencies of regions adjacent the at least one marker by a predetermined amount.

16. The guidewire as recited in claim 15 in which the at least one marker includes a plurality of spherically shaped markers affixed to the flexible wire and spaced along a length of the flexible wire between the proximal end and the distal end of the flexible wire.

17. A catheter for passive tracking with a magnetic resonance imaging (MRI) system, the catheter comprising:
a shaft formed from a flexible material extending from a proximal end to a distal end and configured for insertion into a blood vessel;
a lumen extending through the shaft from the proximal end to the distal end;
a loop formed in the shaft, wherein the loop is configured to receive a bolus of a contrast agent at a concentration and rate that acts to shift magnetic resonance frequencies of regions adjacent the shaft by a predetermined amount.

18. The catheter as recited in claim 17 in which the loop includes an outer extent that is sized so that the loop portion can be positioned with the blood vessel.

19. The catheter as recited in claim 17 in which the concentration is around at least 0.2 millimolar per kilogram bodyweight and the rate is around at least 3 cubic centimeters per second.

20. The catheter as recited in claim 17 further comprising a guidewire for passive tracking with an MRI system and configured to be positioned within the lumen, the guidewire comprising:
a flexible wire extending from a proximal end to a distal end and having an extension axis aligned along a direction along which the wire extends; and
a tip affixed to the distal end, wherein the tip is composed of a material having a bulk magnetic susceptibility that shifts magnetic resonance frequencies of regions adjacent the tip by a predetermined amount, and the tip is shaped such that a substantially same magnetic resonance frequency shift is produced along at least two directions extending outward from the extension axis of the wire.
